(19) United States
(12) Patent Application Publication
(10) Pub. No.: US 2026/0092975 A1
(43) Pub. Date: Apr. 2, 2026

(54) DEVICE AND METHOD FOR ESTIMATING STATE OF CHARGE OF A BATTERY

(71) Applicant: O2Micro Inc., Santa Clara, CA (US)

(72) Inventors: Ming LEI, Wuhan (CN); Jing CHE, Wuhan (CN)

(21) Appl. No.: 19/329,135

(22) Filed: Sep. 15, 2025

(30) Foreign Application Priority Data
Sep. 29, 2024 (CN) 202411375620.3

(51) Int. Cl. G01R 31/367; G01R 31/374; G01R 31/3842

(52) U.S. Cl. CPC G01R 31/367; G01R 31/374; G01R 31/3842

(57) ABSTRACT

In a device operable for determining a state of charge (SOC) of a battery, an acquisition circuit is configured to acquire state parameters of the battery. A processing circuit is configured to: determine a first SOC of the battery by using an AI model based on the state parameters; determine a second SOC of the battery by using a stored lookup table, where the lookup table stores at least a portion of the state parameters and an SOC of the battery in association with each other; and determine a third SOC of the battery by calculating a weighted average of the first SOC of the battery and the second SOC of the battery based on weights of the first SOC of the battery and the second SOC of the battery, where the third SOC represents the SOC of the battery.

### RELATED APPLICATION

This application claims benefit under 35 U.S.C. § 119 (a) to Application No. 202411375620.3, filed with the State Intellectual Property Office of the People's Republic of China on Sep. 29, 2024, which is hereby incorporated by reference in its entirety.

### FIELD

Embodiments according to the present disclosure relate to the technical field of renewable energy technologies, and in particular to battery management technologies.

### BACKGROUND

With the widespread use of battery-powered electronic devices such as mobile phones and handheld computers, accurate presentation of a state of charge (SOC) of a battery has become a critical performance metric for related products. Low SOC accuracy leads to poor user experience, such as uneven changes of battery level, power-off before the battery runs out, and failure to fully charge. The SOC indicates a state of the remaining capacity of the battery, typically expressed as a ratio of the remaining capacity to a fully charged capacity. In the conventional technology, methods for estimating SOC include a discharge test method, an open-circuit voltage (OCV) method, a Coulomb integration method, a hybrid method combining Coulomb integration and OCV, a dynamic voltage method, and the like.

In the discharge test method, constant-current discharge at a certain discharging rate is performed to measure electricity discharged from the battery, so that an SOC value is estimated. This method is generally adopted as a reference standard for battery capacity testing, but is suitable only for laboratory data acquisition due to a stringent test condition. In the OCV method, a relationship between an OCV of a battery and the lithium-ion concentration inside the battery is measured, with which the SOC is estimated indirectly. In this method, the target battery is required to be inactive, e.g., neither charged nor discharged, for more than one hour, and an actual SOC may vary greatly at different temperatures or different stages of a service life of the battery.

In the Coulomb integration method, the SOC of the battery is dynamically estimated by accumulating an amount of electricity during charging and discharging. This method features straightforward calculation, easy implementation, and low requirements for a microprocessor. However, the Coulomb integration method requires prior knowledge of an initial SOC of the battery and is prone to a cumulative error. As an operating condition of a lithium battery changes, a total dischargeable capacity of the battery varies. Particularly, the total dischargeable capacity is significantly decreased when at a low temperature (lower than 0° C.). Due to the cumulative error and the variable total dischargeable capacity, it is difficult to estimate a remaining capacity.

With the hybrid method combining Coulomb integration and OCV, the cumulative error inherent in Coulomb integration is eliminated, but the problem of variation of a total dischargeable capacity of a battery caused by change of an operating condition, such as ambient temperature, is not solved.

The dynamic voltage method is simple in structure and requires low computing power of a microprocessor. Due to an acquisition error of a battery voltage and a nonlinear relationship between the battery voltage and the SOC, accuracy of this method is low. As a result, this method is applicable only to mobile devices seeking low cost and having a low requirement for accuracy.

Therefore, it is necessary to propose a device and a method for estimating a state of charge of a battery, which has low power consumption, small memory footprint, low sensitivity to temperature and other battery-related parameters, broad applicability, and enhanced accuracy.

### SUMMARY

A brief overview of the present disclosure is described below to provide a basic understanding of certain aspects of the present disclosure. This summary is not an exhaustive summary of the present disclosure. It is not intended to identify the key or important parts of the present disclosure, nor is it intended to limit the scope of the present disclosure. Its purpose is merely to present concepts in a simplified form, which serves as a preamble of a more detailed description to be discussed later.

According to an aspect of the present disclosure, a device for determining a state of charge of a battery is provided. The device includes: an acquisition circuit, configured to acquire state parameters of the battery; and a processing circuit, configured to: calculate a first state of charge of the battery using a trained artificial intelligence (AI) model based on the state parameters acquired by the acquisition circuit; determine a second state of charge of the battery using a pre-stored lookup table based on the state parameters acquired by the acquisition circuit, where the lookup table stores at least a portion of the state parameters and a state of charge of the battery in association with each other; and determine a third state of charge of the battery by calculating a weighted average of the first state of charge of the battery and the second state of charge of the battery based on weights of the first state of charge of the battery and the second state of charge of the battery, where the third state of charge represents the state of charge of the battery.

According to an aspect of the present disclosure, a method for determining a state of charge of a battery is provided. The method includes: acquiring state parameters of the battery; calculating a first state of charge of the battery using a trained AI model based on the acquired state parameters; determining a second state of charge of the battery using a stored lookup table based on the acquired state parameters, where the lookup table stores at least a portion of the state parameters and a state of charge of the battery in association with each other; and determining a third state of charge of the battery by calculating a weighted average of the first state of charge of the battery and the second state of charge of the battery based on weights of the first state of charge of the battery and the second state of charge of the battery, where the third state of charge represents the state of charge of the battery.

According to other aspects of the present disclosure, computer program codes and a computer program product for implementing the above-described method and a computer-readable storage medium storing the computer program codes for implementing the above-described method are further provided.

With the device and the method according to the present disclosure, the state of charge of the battery estimated by using the trained AI model and the state of charge of the battery estimated by using the stored lookup table are obtained respectively, and filtering is performed thereon to obtain a final estimated state of charge of the battery. In this way, the estimation of state of charge of the battery is widely applicable and has enhanced accuracy.

These and other advantages of the present disclosure become more apparent through embodiments of the present disclosure described in detail below in conjunction with accompanying drawings.

### BRIEF DESCRIPTION OF THE DRAWINGS

To further set forth the above and other advantages and features of the present disclosure, detailed descriptions are made for implementations of the present disclosure in the following in conjunction with accompanying drawings. The drawings, together with the detailed description below, are incorporated into and form a part of the specification. Elements having the same function and structure may be denoted by the same reference numerals. The accompanying drawings only illustrate typical embodiments of the present disclosure and should not be construed as a limitation to the scope of the present disclosure. In the accompanying drawings:

FIG. 1 is a block diagram showing functional modules of a device for estimating a state of charge of a battery according to a first embodiment of the present invention;

FIG. 2 is a diagram showing an exemplary artificial intelligence (AI) model according to a first embodiment of the present invention;

FIG. 3 shows an example of a fitted curve for an open-circuit voltage U_{oc} and a SOC of a battery according to a first embodiment of the present invention;

FIG. 4 is a flowchart of an example of an RC table lookup method based on three-dimensional linear interpolation according to a first embodiment of the present invention;

FIG. 5 is a block diagram showing functional modules of a device for estimating a state of charge of a battery according to a second embodiment of the present invention;

FIG. 6 is a flowchart of an example of a calculation process of a cubature Kalman filter (CKF) model in an embodiment according to the present invention;

FIG. 7 illustrates a flowchart of an example of a method for estimating a state of charge of a battery in an embodiment according to the present invention;

FIG. 8(a) illustrates an example of a comparison graph among an estimated SOC from an AI module, an estimated SOC from a table lookup module, and a real RSOC of a battery when being discharged at a current point of 1600 mA in a temperature of −10° C., in embodiments according to the present invention;

FIG. 8(b) illustrates an example of a comparison graph among an estimated SOC from an AI module, an estimated SOC from a table lookup module, and a real RSOC of a battery when being discharged at a current point of 2500 mA in a temperature of −10° C., in embodiments according to the present invention;

FIG. 9(a) illustrates an example of a comparison graph among an estimated SOC outputted by a second filtering module, an estimated SOC from an AI module, an estimated SOC from a table lookup module, and a real RSOC of a battery when being discharged at a current point of 1600 mA in a temperature of −10° C., in embodiments according to the present invention;

FIG. 9(b) illustrates an example of a comparison graph among an estimated SOC outputted by a second filtering module, an estimated SOC from an AI module, an estimated SOC from a table lookup module, and a real RSOC of a battery when being discharged at a current point of 2500 mA in a temperature of −10° C., in embodiments according to the present invention; and

FIG. 10 illustrates an example of a comparison graph between an estimated SOC and a real RSOC of a battery in a single charge and discharge process in a temperature of 25° C., in embodiments according to the present invention.

### DETAILED DESCRIPTION

Embodiments of the present disclosure are described herein in conjunction with the accompanying drawings. For the sake of clarity and conciseness, not all of the features of practical implementations are described in the specification. However, during a process of developing any such embodiment, many decisions specific to the embodiment have to be made, to achieve a specific target of a developer, such as to conform to limitation conditions related to a system and service. The limitation conditions may change for different embodiments. Furthermore, although the development work may be complicated and time-consuming, such development work is only a routine task for those skilled in the art benefiting from the present disclosure.

Herein, in order to avoid obscuring the present disclosure due to unnecessary details, only device structures and/or processing steps closely related to the solutions according to the present disclosure are illustrated in the drawings, and other details less related to the present disclosure are omitted. In some instances, well-known methods, procedures, components, and circuits have not been described in detail so as not to unnecessarily obscure aspects of the present disclosure.

Reference will now be made in detail to the various embodiments of the present disclosure, examples of which are illustrated in the accompanying drawings. While described in conjunction with these embodiments, they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, the present disclosure may be practiced without these specific details. In other instances, well-known methods, procedures, components, and circuits have not been described in detail so as not to unnecessarily obscure aspects of the present disclosure.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

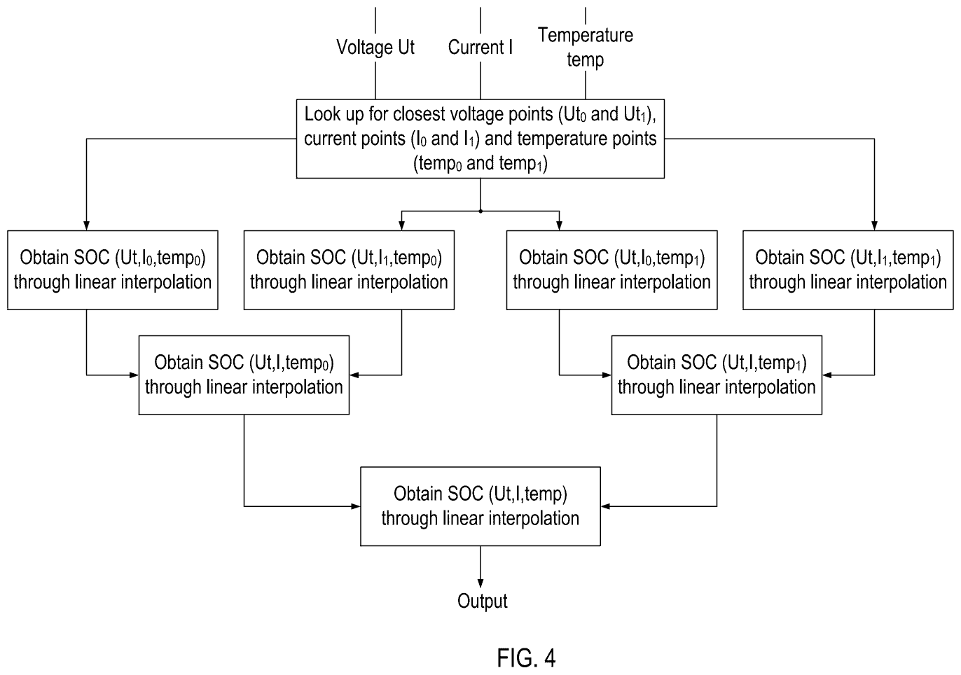

It should be borne in mind, however, that all of these and similar terms are to be associated with the appropriate physical quantities and are merely convenient labels applied to these quantities. Unless specifically stated otherwise as apparent from the following discussions, it is appreciated that throughout the present disclosure, discussions utilizing terms such as “calculating,” “obtaining,” “performing,” “acquiring,” “storing,” “determining,” or the like, may refer to actions and processes (e.g., the processes and flowcharts of FIGS. 4, 6, and 7) of an apparatus or computer system or similar electronic computing device or processor. A computer system or similar electronic computing device manipulates and transforms data represented as physical (electronic) quantities within memories, registers or other such information storage, transmission or display devices. In its most basic configuration, a computer system or the like includes at least one processing unit and memory. The computer system may also have additional features and/or functionality, such as the capability for communicating with other devices, the capability to receive user inputs, and the capability to display results.

Embodiments described herein may be discussed in the general context of computer-executable instructions residing on some form of computer-readable storage medium, such as modules, executed by one or more computers, other devices, or circuits. By way of example, and not limitation, computer-readable storage media may comprise non-transitory computer storage media and communication media. Generally, modules may include software, routines, programs, objects, components, data structures, etc., that perform particular tasks or implement particular abstract data types. The functionality of the modules may be combined or distributed as desired in various embodiments. Modules may also be implemented using circuits such as an acquisition circuit or a processing circuit (e.g., a chip or a processor). Moreover, the modules are merely logical modules defined based on specific functions implemented by the modules and are not intended to limit an implementation. For example, a module may be implemented by one or more application-specific integrated circuits, software programs, or a combination thereof.

Computer storage media includes volatile and nonvolatile, removable and non-removable media implemented in any method or technology for storage of information such as computer-readable instructions, data structures, program modules or other data. Computer storage media includes, but is not limited to, random access memory (RAM), read only memory (ROM), electrically erasable programmable ROM (EEPROM), flash memory (e.g., an SSD) or other memory technology, compact disk ROM (CD-ROM), digital versatile disks (DVDs) or other optical storage, magnetic cassettes, magnetic tape, magnetic disk storage or other magnetic storage devices, or any other medium that can be used to store the desired information and that can accessed to retrieve that information.

Communication media may embody computer-executable instructions, data structures, and modules, and includes any information delivery media. By way of example, and not limitation, communication media may include wired media such as a wired network or direct-wired connection, and wireless media such as acoustic, radio frequency (RF), infrared and other wireless media. Combinations of any of the above can also be included within the scope of computer-readable media.

As used herein, the term “parameter” or the like may be the name of a property or metric (e.g., “temperature”) or the numerical value of that property or metric (e.g., 90° C.). A person of ordinary skill in the art will understand how the term is being used.

### First Embodiment

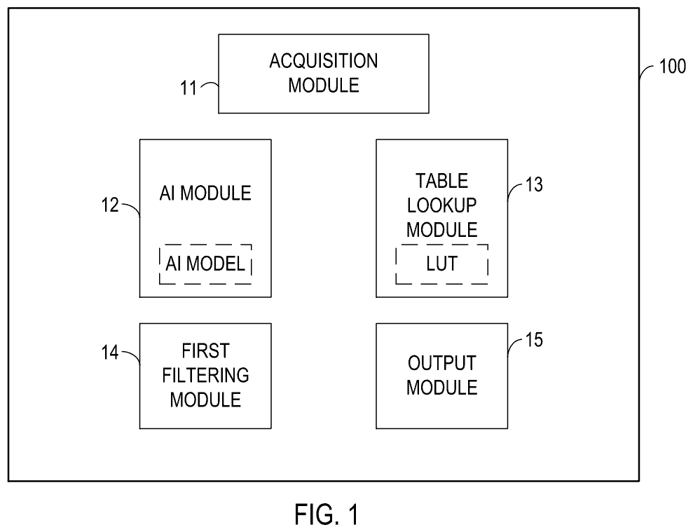

FIG. 1 is a block diagram illustrating functional modules of a device 100 for estimating a state of charge (SOC) of a battery according to a first embodiment of the present invention. As shown in FIG. 1, the device 100 includes an acquisition module 11, an AI (artificial intelligence) module 12, a table lookup module 13, a first filtering module 14, and an output module 15. An input of the device 100 is a state parameter acquired by the acquisition module 11, and an output of the device 100 is an output value of the output module 15. The AI module 12, the table lookup module 13, the first filtering module 14, and the output module 15 may be implemented by a processing circuit.

In the device 100: the acquisition module 11 is configured to acquire a state parameter of the battery; the AI model 12 is configured to calculate a first state of charge of the battery, by using a pre-trained AI model, based on the state parameter acquired by the acquisition module 11; the table lookup module 13 is configured to obtain a second state of charge of the battery, using a pre-stored lookup table, based on the state parameter acquired by acquisition module 11, where the lookup table stores at least a portion of the state parameter and a state of charge of the battery in association with each other; the first filtering module 14 is configured to obtain a third state of charge of the battery by calculating a weighted average of the first state of charge and the second state of charge based on weights of the first state of charge and the second state of charge; and the output module 15 is configured to determine the third state of charge as an estimated state of charge of the battery.

The acquisition module 11 may be implemented by an acquisition circuit. In an embodiment, the acquisition circuit includes at least one sensor, and acquires a state parameter of a target battery through the at least one sensor. The state parameter of the target battery may include, for example, at least one of an open-circuit voltage, a terminal voltage, a current, and a temperature of the target battery, but is not limited thereto. The temperature (temp) is obtained, for example, by a temperature sensor. The current (I) is obtained by a current sensing circuit. The open-circuit voltage (U_{oc}) and the terminal voltage (Uₜ) are obtained, for example, by a voltage sensing circuit. Known temperature sensors, current sensing circuits, and voltage sensing circuits may be used. The acquisition module 11 transmits the acquired state parameter of the target battery to the AI module 12 and the table lookup module 13.

The AI module 12, the table lookup module 13, the first filtering module 14, and the output module 15 may be implemented by one or more processing circuits. Each of the processing circuits may be implemented by, for example, a chip or a processor. Moreover, it should be understood that the modules are merely logical modules defined based on specific functions implemented by the modules and are not intended to limit an implementation. For example, one or more of the modules may be implemented by one or more application-specific integrated circuits and/or software programs.

As described above, the AI module 12 is configured to calculate the first state of charge of the battery by using a trained AI model based on the state parameter acquired by the acquisition module 11.

The AI module 12 includes the trained AI model (which is trained on data of multiple batteries of a same type, for example). The AI model may be inputted with the acquired state parameter (for example, at least one or all of a present current I, a present terminal voltage Uₜ, and/or a present temperature temp) and perform calculation(s) to obtain a first state of charge SOC_{AI} of the battery.

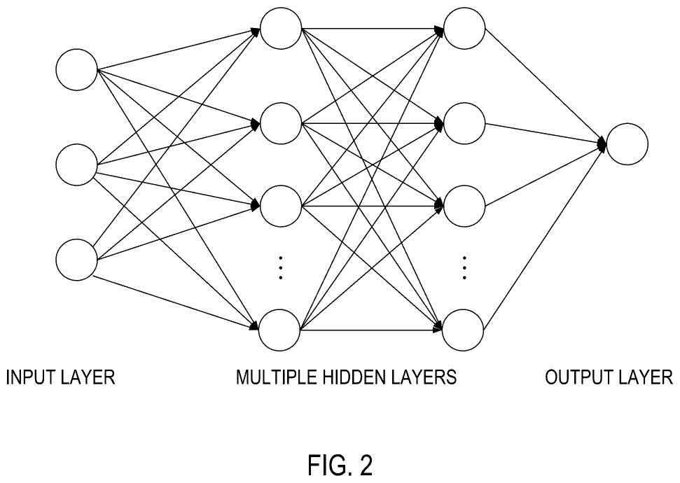

FIG. 2 illustrates an example of an AI model according to the first embodiment. In this example, the AI model is a multi-layer neural network model including an input layer, at least two hidden layers, and an output layer. The input layer is for inputting a state parameter of the battery. Each hidden layer is provided with multiple neural network nodes, and each of the neural network nodes is assigned with an activation function. The output layer is for outputting the first state of charge calculated through the multi-layer neural network model. In the example, the AI model includes two hidden layers; however, the example is not limiting. The present current I, the present terminal voltage Uₜ, and the present temperature temp of the battery are input at the input layer. The inputs to each neural network node in each hidden layer can include a value of an input variable or a value that is an output of a neural node in a previous layer. An output of a single neural node may be expressed as y=f(SUM), where

$$SUM = {\sum }_{i = 1}^{n} {a}_{i} {w}_{i} + b ; {a}_{1} , … , {a}_{n}$$

represent input values; w₁, . . . , wₙ represent weights of the input values; b represents a bias of a present neural node; and f represents an activation function. An output from the output layer is an SOC value, SOC_{AI}, that is the result of a calculation by the multi-layer neural network model.

Generally, the activation function f is for data truncation, data smoothing, or the like. Common types of activation functions include: linear, tanh, sigmoid, relu, leaky, mish, and the like. Non-limiting examples of an operational formula of the activation function (with an input represented by x and output represented by y) are listed below in Table 1.

TABLE 1
Operational Formula of Activation Function

| Activation Function | Operational Formula |
|---|---|
| Linear | y = x |
| Tanh | y = tanh(x) |
| Sigmoid | y = 1/(1 + e^{-x}) |
| Relu | if(x < 0) y = 0; |
| | else y = x; |
| Leaky | if(x < 0) y = x/k; |
| | (k > 1, is a constant) |
| | else y = x; |
| Mish | y = x*tanh(ln(1 + e^{x})) |

An activation function that is of the linear, relu, or leaky type features simple operations and low power consumption for neural network training, and therefore is preferably applied in the AI model in an embodiment, which is not limiting.

For the sake of brief description, in the first embodiment, the example of the AI model shown in FIG. 2 is in simplified form in a multi-layer neural network model MLP. The example does not constitute a limitation on the present disclosure. In practice, with reference to FIG. 1, other proper variants of the multi-layer neural network model or other neural network models may be applied in the AI module 12 in the present embodiment, as long as they are properly trained and capable of obtaining the first state of charge SOC_{AI} of the battery based on the state parameter acquired by the acquisition module 11. In an example, the AI model may be implemented as a variant of a specific multi-layer neural network such as a convolutional neural network, a recurrent neural network, or a long short-term memory network, which are known in the art and so are not described in further detail here.

The table lookup module 13 is configured to determine the SOC of the battery by using a stored lookup table (LUT). For example, the stored lookup table may include at least one of an open-circuit voltage (OCV) table or a resistor-capacitor (RC) table. The table lookup module 13 obtains a second state of charge SOCₗᵤₜ of the battery by using the pre-stored lookup table based on the state parameter acquired by the acquisition module 11. The table lookup module 13 is further configured to selectively perform a lookup from the open-circuit voltage table or the RC table according to a predetermined condition, and determine an output value as the second state of charge SOCₗᵤₜ of the battery. The lookup table is generated by measuring the battery in advance.

For example, the open-circuit voltage table stores a correspondence between a state of charge and an open-circuit voltage of the battery in association with each other, and the RC table stores a correspondence between a state of charge of the battery and a terminal voltage, current, and temperature in association with each other. In other words, the open-circuit voltage table includes values of SOC as a function of (indexed by) respective values of open-circuit voltages, and the RC table includes values of SOC as a function of (indexed by) respective combinations of values of terminal voltage, current, and temperature. The open-circuit voltage table may be represented as OCV (SOC, U_{oc}), and the RC table may be represented as RC (SOC, Uₜ, I, temp).

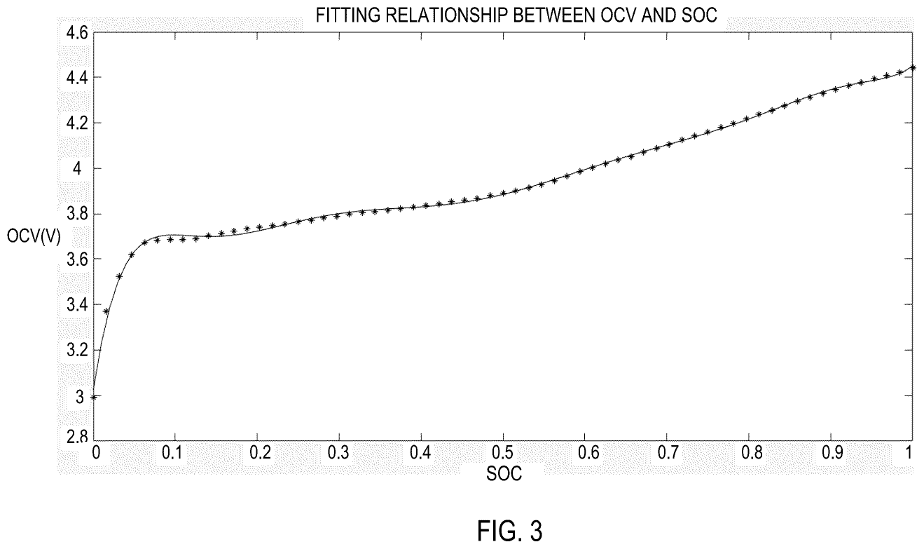

During a lookup using the open-circuit voltage table, the table lookup module 13 is configured to determine an estimation result of a real-time state of charge of the battery through a lookup based on an open-circuit voltage acquired by the acquisition module 11 according to a predefined correspondence between an open-circuit voltage U_{oc} and a SOC of the battery; and determine the estimation result as an output SOC_{OC} of the lookup in the open-circuit voltage table. The predefined correspondence between an open-circuit voltage U_{oc} and a SOC of the battery may be a predetermined fitting function based on battery characteristics. An OCV-SOC rapid calibration experiment and the like are executed on a test battery in an earlier stage to obtain data of the U_{oc} and SOC, and then data fitting is performed. For ease of understanding, FIG. 3 shows an example of a fitting relationship between open-circuit voltage and SOC for a chosen test battery.

In a non-limiting embodiment, a lookup from the open-circuit voltage table is performed with one-dimensional linear interpolation. The one-dimensional linear interpolation is exemplified by the following equation:

$${SOC}_{oc} = \frac{{SOC}_{oc 1} - {SOC}_{oc 0}}{{U}_{oc 1} - {U}_{oc 0}} * ( {U}_{oc} - {U}_{oc 0} ) + {SOC}_{oc 0} .$$

In the above equation, U_{oc0} and U_{oc1} represent voltage points closest to U_{oc}; SOC_{oc1} and SOC_{oc0} represent SOC values corresponding to U_{oc0} and U_{oc1}, respectively; and SOC_{OC} represents an output value obtained through a lookup using the open-circuit voltage table.

During a lookup from the RC table, the table lookup module 13 is configured to determine a calculation result of a state of charge of the battery through fitting with reference to existing data in the RC table based on a state parameter acquired by the acquisition module 11, and determine the calculation result as an output SOC_{Ut,I,temp} of the lookup in the RC table. The state parameter used for a lookup in the RC table is, for example, a present current I, a present terminal voltage Uₜ, and a present temperature temp.

In a non-limiting embodiment, a lookup in the RC table is performed with three-dimensional linear interpolation.

FIG. 4 is a flowchart showing an example of an RC table lookup method performed with three-dimensional linear interpolation according to the first embodiment. In the example of FIG. 4, the table lookup module 13 is configured to perform the following steps.

In step 1, voltage points Uₜ₀ and Uₜ₁ that are closest to a terminal voltage Uₜ, current points I₀ and I₁ that are closest to a current I, and temperature points temp₀ and temp₁ that are closest to a temperature temp are found in the RC table. The terminal voltage U, the current I, and the temperature temp are parameters measured by the acquisition module 11.

In step 2, the following operations are performed by the table lookup module 13.
(1) SOC_{Ut0,I0,temp0} (corresponding to the terminal voltage Uₜ₀, current I₀ and temperature point temp₀), and SOC_{Ut1,I0,temp0} (corresponding to the terminal voltage Uₜ₁, current I₀ and the temperature point temp₀), are determined using (looked up in) the RC table. Interpolation of the RC table values is performed by the table lookup module 13 as:

$$SO \text{?} = \frac{SO \text{?} - SO \text{?}}{{U}_{t 1} - {U}_{t 0}} * ( {U}_{t} - {U}_{t 0} ) + SO \text{?}$$

$$\text{?} \text{indicates text missing or illegible when filed}$$

(2) SOC_{Ut0,I1,temp0} (corresponding to the terminal voltage Uₜ₀, current I₁ and temperature point temp₀), and SOC_{Ut1,I1,temp0} (corresponding to the terminal voltage Uₜ₁, current I₁ and temperature point temp₀), are looked up in the RC table. Interpolation of the RC table values is performed by the table lookup module 13 as:

$$SO \text{?} = \frac{SO \text{?} - SO \text{?}}{{U}_{t 1} - {U}_{t 0}} * ( {U}_{t} - {U}_{t 0} ) + SO \text{?}$$

$$\text{?} \text{indicates text missing or illegible when filed}$$

(3) SOC_{Ut0,I0,temp1} (corresponding to the terminal voltage Uₜ₀, current I₀ and temperature point temp₁), and SOC_{Ut1,I0,temp1} (corresponding to the terminal voltage Uₜ₁, current I₀ and temperature point temp₁), are looked up in the RC table. Interpolation of the RC table values is performed by the table lookup module 13 as:

$$SO \text{?} = \frac{SO \text{?} - SO \text{?}}{{U}_{t 1} - {U}_{t 0}} * ( {U}_{t} - {U}_{t 0} ) + SO \text{?}$$

$$\text{?} \text{indicates text missing or illegible when filed}$$

(4) SOC_{Ut0,I1,temp1} (corresponding to the terminal voltage Uₜ₀, current I₁ and temperature point temp₁), and SOC_{Ut1,I1,temp1} (corresponding to the terminal voltage Uₜ₁, current I₁ and the temperature point temp₁), are looked up in the RC table. Interpolation of the RC table values is performed by the table lookup module 13 as:

$$SO \text{?} = \frac{SO \text{?} - SO \text{?}}{{U}_{t 1} - {U}_{t 0}} * ( {U}_{t} - {U}_{t 0} ) + SO \text{?}$$

$$\text{?} \text{indicates text missing or illegible when filed}$$

In step 3, the following operations are performed by the table lookup module 13.
(1) Interpolation is performed using the values of SOC_{Ut,I0,temp0} and SOC_{Ut,I1,temp0} calculated in step 2, obtaining:

$$SO \text{?} = \frac{SO \text{?} - SO \text{?}}{{I}_{1} - {I}_{0}} * ( I - {I}_{0} ) + SO \text{?}$$

$$\text{?} \text{indicates text missing or illegible when filed}$$

(2) Interpolation is performed using the values of SOC_{Ut,I0,temp1} and SOC_{Ut,I1,temp1} calculated in step 2, obtaining:

$$SO \text{?} = \frac{SO \text{?} - SO \text{?}}{{I}_{1} - {I}_{0}} * ( I - {I}_{0} ) + SO \text{?} .$$

$$\text{?} \text{indicates text missing or illegible when filed}$$

In step 4, interpolation is performed by the table lookup module 13 using the values of SOC_{Ut,I,temp0} and SOC_{Ut,I,temp1} calculated in step 3, obtaining:

$$SO \text{?} = \frac{SO \text{?} - SO \text{?}}{{temp}_{1} - {temp}_{0}} * ( temp - {temp}_{0} ) + SO \text{?} ,$$

$$\text{?} \text{indicates text missing or illegible when filed}$$

where SOC_{Ut,I,temp} is determined as an output of the lookup in the RC table.

In an example configuration, the table lookup module 13 is configured to: perform lookups in the open-circuit voltage table in cases where the battery is in an idle state, a constant-voltage charging state, or a low-current charging or discharging state; and perform lookups in the RC table in cases otherwise, where the battery is in a state other than the idle state, the constant-voltage charging state, and the low-current charging or discharging state. Generally, in the RC table, voltage sampling points are more discrete (finer) than current sampling points and temperature sampling points. For example, the RC table may store six (6) temperature points (e.g., −10° C., 0° C., 15° C., 25° C., 40° C. and 45° C.), 6 current points (e.g., 600 mA, 800 mA, 1200 mA, 1600 mA, 2000 mA and 2500 mA), and 73 voltage points. A lookup in the OCV table is introduced as a supplement when/if a current value I is less than the minimum current point in the RC table. For example, a current less than 600 mA in the above example is considered to be a low current.

In an implementation, the table lookup module 13 may be configured to determine whether the battery is in one of the following states: the idle state, the constant-voltage charging state, or the low-current charging or discharging state. If the battery is in one of these states, a lookup is performed in the OCV table and a lookup result SOC_{OC} is output from the table lookup module 13 as a lookup output result SOCₗᵤₜ. If the battery is not in one of these states, a lookup is performed only in the RC table and a lookup result SOC_{Ut,I,temp} is output from the table lookup module 13 as a lookup output result SOCₗᵤₜ.

With reference to FIG. 1, the first filtering module 14 receives the output (the first state of charge of the battery) SOC_{AI} from the AI module 12 and the output (the second state of charge of the battery) SOCₗᵤₜ from the table lookup module 13, and calculates a weighted average of the first state of charge and the second state of charge based on weights of the first state of charge and the second state of charge, to obtain a third state of charge of the battery. The output module 15 outputs the third state of charge as an estimated state of charge of the battery.

In an embodiment, the values of the first weight and the second weight are chosen so that their sum is equal to one (1), and a calculation result of the weighted average SOC_{AI|lut} of the first state of charge and the second state of charge is determined as the third state of charge. Accordingly, the first filtering module 14 may be considered as performing low-pass filtering on the first state of charge and the second state of charge. The calculation performed the first filtering module 14 may be expressed as:

$$SO \text{?} = weight * SO \text{?} + ( 1 - weight ) * {SO}_{lut} .$$

$$\text{?} \text{indicates text missing or illegible when filed}$$

In the above equation, a first weight (“weight”) corresponding to the first state of charge and a second weight (“1-weight”) corresponding to the second state of charge may be determined based on at least one state parameter of the battery. In an example, the first weight and the second weight are determined based on at least a present temperature temp of the battery. Furthermore, the first weight and the second weight may be adjusted based on an accuracy of the first state of charge and an accuracy of the second state of charge. That is, a value of the weight in the above equation may be adjusted to compensate for temperature or other factors.

If one of the first state of charge and the second state of charge has a higher accuracy than the other, the higher accuracy value may be assigned a greater weight than the other. For example, considering the differences in estimation accuracy of the AI module 12 and the table lookup module 13 at different temperatures, the weight of the first state of charge is selected so that it is greater than the weight of the second state of charge when the temperature is within a first temperature range, and the weight of the first state of charge is selected so that it is less than the weight of the second state of charge when the temperature is within a second temperature range that is higher than the first temperature range.

In an implementation, for some batteries at a normal temperature (such as within a range from 15° C. to 30° C. or higher), SOCₗᵤₜ obtained through a table lookup has a higher accuracy than SOC_{AI} calculated by an AI model, and therefore the first weight (weight) is set to be less than the second weight (1-weight) in order to improve the estimation accuracy. The above-described temperature example does not constitute a limitation on the technical solution of the present disclosure. The first weight and the second weight may be set based on other factors. For example, the first weight and the second weight may be further adjusted depending on different batteries or based on other conditions, such as a real-time current or voltage, so as to improve the estimation accuracy.

In an example, the weight is determined based on a range within which the measured temperature falls and a range within which the measured current falls. In a case where the current is outside a current range stored in a lookup table, the weight of the first state of charge and the weight of the second state of charge are both set to predefined constant values. In a case where the current falls within the current range stored in the lookup table, the weight of the first state of charge is a first function of the temperature for a first temperature range; and the weight of the first state of charge is a second function of the temperature for a second temperature range.

An example functional relationship between the weight of the first state of charge and the weight of the second state of charge is provided below. Since the sum of the two weights is equal to 1, only the functional relationship of the weight (weight) of the first state of charge is provided as follows:

$$weight = \{ \text{} \begin{matrix}0.85 , \vert \text{?} \vert > Maximum current point , \vert \text{?} \vert < Minimum current point \\ \begin{matrix}0.7 + 0.01 \times ( 15 - temp ) , - 15 \leq temp < 15 , Minimum current point \leq \\ \vert \text{?} \vert \leq Maximum current point\end{matrix} \\ \begin{matrix}0.2 - 0.01 \times ( temp - 25 ) , 15 \leq temp \leq 45 , Minimum current point \leq \\ \vert \text{?} \vert \leq Maximum current point\end{matrix}\end{matrix}$$

$$\text{?} \text{indicates text missing or illegible when filed}$$

Here, the maximum current point represents a maximum current value stored in the RC table, and the minimum current point represents a minimum current value stored in the RC table. The above functional relationship is not limiting. Other linear or nonlinear functional relationships (single-segment or multi-segment functions) may be adopted to describe a process in which the weight decreases as the temperature increases, without departing from the technical concept of the present disclosure.

In a case where the current is outside the current range stored in the RC table, the weight of the first state of charge is greater than the weight of the second state of charge. In this case, the weight of the first state of charge may be greater than or equal to 0.5, preferably greater than or equal to 0.75, and more preferably greater than or equal to 0.85. In the above example functional relationship, the weight of the first state is set at 0.85.

In a case where the current falls within the current range stored in the RC table, the weight of the first state of charge is greater than the weight of the second state of charge if the temperature falls within a first temperature range, and the weight of the first state of charge is less than the weight of the second state of charge if the temperature falls within a second temperature range that is higher than the first temperature range. In addition, in an implementation, if the temperature is within the first temperature range or the second temperature range, the weight of the first state of charge decreases as the temperature increases.

In an example, a demarcation point between the first (lower) temperature range and the second (higher) temperature range is within a range from 10° C. to 25° C. (that is, the minimum value of the second range is 10° C. to 25° C. higher than the maximum value of the first range). Preferably, the demarcation point is within a range from 15° C. to 20° C. More preferably, the demarcation point is around 15° C. or, for example, a range of ±20% to ±10% of 15° C.

In addition, the weight is strongly correlated with the temperature temp, a low current I (a current lower than the minimum current point), and a high current I (a current higher than the maximum current point). In a current range in the RC table, the weight is relatively weakly correlated with the terminal voltage Uₜ.

The output module 15 is configured to receive the third state of charge SOC_{AI|lut}, output by the first filtering module 14, and to specify the third state of charge SOC_{AI|lut} as the estimated state of charge output by the device 100.

In the embodiment, the AI module 12 is further configured to further train the pre-trained AI model with the estimated state of charge of the battery and a corresponding state parameter to optimize a model parameter of the AI model. In an implementation, the AI model is configured as an iterative multi-layer neural network model, and may be further trained based on the third state of charge SOC_{AI|lut} output by the output module 15 and the corresponding state parameter (such as a present current I, a present terminal voltage Uₜ, and a present temperature temp). The training is performed for a specific battery in a specific operating environment, and is conducive to improving the estimation accuracy of the AI model. For example, the AI module may calculate a gradient and update the weight and bias through back propagation based on the estimated state of charge of the battery and a corresponding state parameter. This process is iterated until the trained multi-layer neural network model converges (that is, a loss function reaches a minimum value).

In other embodiments, the AI module 12 is configured to utilize a fixed trained AI model without performing further training, so that computing resources are saved and overall complexity is simplified.

With the device 100 according to the embodiment, the state of charge of the battery estimated by using the pre-trained AI model, and the state of charge of the battery estimated by using the pre-stored lookup table are obtained, and weight-based filtering is performed thereon to obtain a final estimated state of charge. An error in estimating the state of charge caused by temperature, battery operating state and other factors is reduced, the estimation accuracy is improved, and thereby a wider applicability is achieved. Further, the AI model is further trained with a real-time estimation result of the state of charge, so that the accuracy and stability of estimation of the state of charge are further and continually improved.

### Second Embodiment

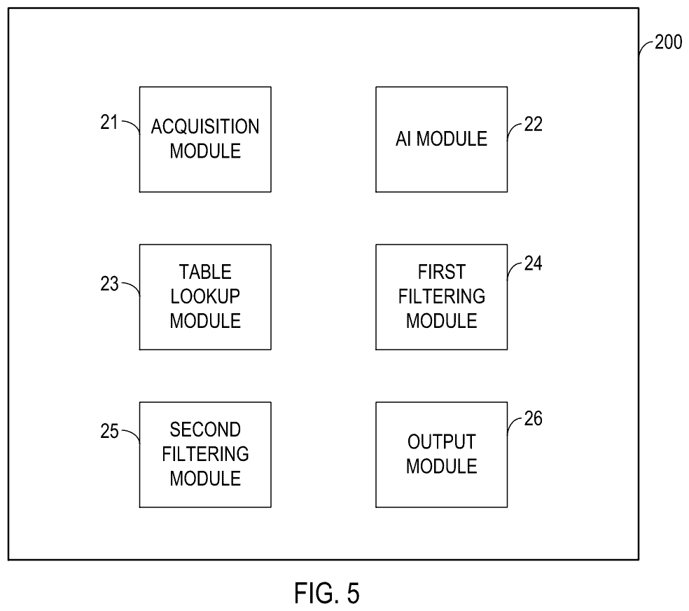

FIG. 5 is a block diagram showing functional modules of a device 200 for estimating a state of charge of a battery according to a second embodiment.

As shown in FIG. 5, the device 200 includes an acquisition module 21, an AI module 22, a table lookup module 23, a first filtering module 24, a second filtering module 25, and an output module 26. The acquisition module 21, the AI module 22, the table lookup module 23 and the first filtering module 24 have the same structure and functionality as the acquisition module 11, the AI module 12, the table lookup module 13 and the first filtering module 14 of the device 100 described in the first embodiment. The acquisition module 21 is configured to acquire a state parameter of the battery. The AI module 22 is configured to calculate a first state of charge of the battery using a trained AI model based on the state parameter acquired by the acquisition module 21. The table lookup module 23 is configured to obtain a second state of charge of the battery using a stored lookup table based on the state parameter acquired by the acquisition circuit. The first filtering module 24 is configured to obtain a third state of charge of the battery by calculating a weighted average of the first state of charge and the second state of charge using weights of the first state of charge and the second state of charge. Specific details thereof are provided above in the discussion of the first embodiment and are not repeated here.

The device 200 is distinguished from the device 100 in that the device 200 further includes a second filtering module 25. The second filtering module 25 is configured to determine a fourth state of charge through Kalman filtering based on the third state of charge and the state parameter acquired by the acquisition circuit. Furthermore, the output module 26 is configured to determine the fourth state of charge SOC_{KF} as the state of charge of the battery estimated by the device 200.

That is, the device 200 according to the second embodiment is distinguished from the device 100 according to the first embodiment in that, in the device 200, the third state of charge SOC_{AI|lut} output by the first filtering module 24 and the state parameters (a present current I, present terminal voltage Uₜ, and present temperature temp) output by the acquisition module 21 are input to the second filtering module 25 for Kalman filtering, and a filtering result is determined as the fourth state of charge SOC. Furthermore, the fourth state of charge SOC_{KF} output by the output module 26 and the corresponding state parameters (for example, the present current I, present terminal voltage Uₜ and present temperature temp) may be input to the AI model of the AI module 22 for further training of the AI model. For example, the AI module 22 calculates a gradient, and updates a weight and bias through back propagation. The process is iterated until the trained multi-layer neural network model converges (that is, a loss function reaches a minimum value). In this way, adaptability of the AI model to the present battery and operating state is further improved, and thereby the estimation accuracy and stability are improved.

The second filtering module 25 based on a Kalman filtering model is described below.

The Kalman filtering model of the second filtering module 25 includes a state equation and a measurement equation as follows.

The state equation is:

$$\{ \begin{matrix}{U}_{p , k} = ( 1 - \frac{Δ t}{τ} ) * {U}_{p , k - 1} + \frac{Δ t}{{C}_{P}} * {I}_{k - 1} + {w}_{1} \\ {SOC}_{k} = {SOC}_{k - 1} + \frac{{I}_{k - 1} * Δ t}{{C}_{N}} + {w}_{2}\end{matrix}$$

The measurement equation is:

$$\{ \begin{matrix}{U}_{t , k} = {U}_{oc} - {U}_{p , k} - {R}_{0} * {I}_{k} + {v}_{1} \\ {SOC}_{k} = SO \text{?} + {v}_{2}\end{matrix}$$

$$\text{?} \text{indicates text missing or illegible when filed}$$

In these equations, a polarization voltage Uₚ and a state of charge SOC are state variables, Δt represents a sampling time, C_{N} represents a rated battery capacity, R₀ represents a battery internal resistance, t represents a time constant, Cₚ represents a polarization capacitance, U_{oc} represents an open-circuit voltage, w₁ and w₂ represent system noises, and v₁ and v₂ represent measurement noises. Circuit model parameters R₀, τ, and Cₚ in the state equation may be estimated through a recursive least squares method.

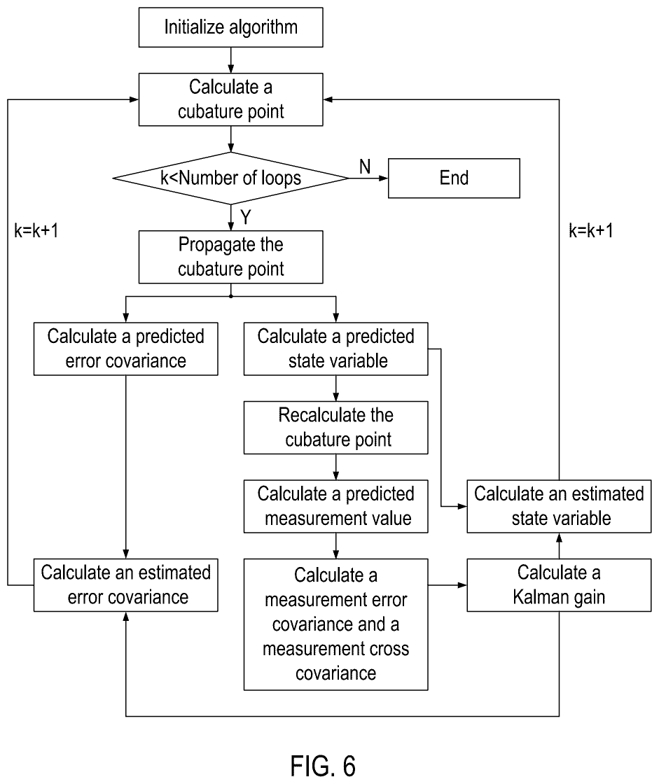

FIG. 6 is a flowchart of an embodiment of a calculation process of a cubature Kalman filter (CKF) model. In the cubature Kalman filter method, a third-degree spherical-radial cubature rule is applied for calculating 2n (where n represents the quantity of state variables). In the present embodiment, polarization voltage Uₚ and state of charge SOC are state variables, and therefore n equals 2. A calculation process of the Kalman filter model is described below with reference to FIG. 6.

The calculation process is initialized using the following equations:

$$\{ \begin{matrix}\text{?} = {x}_{0} \\ \text{?} = \text{?}\end{matrix}$$

$$\text{?} \text{indicates text missing or illegible when filed}$$

Here, k=1, 2, . . . , N; x₀ represents an initial value of a state variable; Rₖ₋₁ represents an estimated value of a state variable at a time instant k−1; and Pₖ₋₁ represents an error covariance at the time instant k−1. Cholesky decomposition on an initial value P₀ derives S₀.

After initialization, a cubature point is calculated as:

$${X}_{j , k - 1} = {S}_{k − 1} ξ \text{?} + {\hat{x}}_{k − 1}$$

$$\text{?} \text{indicates text missing or illegible when filed}$$

Here, m=4 represents the quantity of cubature points, and

$$ξ \text{?} = \sqrt{\frac{m}{2}} [ 1 ] \text{?} , j = 1 , … , m ,$$

$$\text{?} \text{indicates text missing or illegible when filed}$$

where [1]ⱼ represents a j-th point in a point set [1].

According to the third-degree spherical-radial rule, the quantity of the cubature points is twice a dimension n of a state vector. As [1]ₜ represents an i-th cubature point, there has:

$$[ 1 ] \text{?} = \{ ( \begin{matrix}\begin{matrix}\begin{matrix}1 \\ 0\end{matrix} \\ ⋮\end{matrix} \\ 0\end{matrix} ) , ( \begin{matrix}0 \\ 1 \\ ⋮ \\ 0\end{matrix} ) , ⋯ , ( \begin{matrix}\begin{matrix}0 \\ 0 \\ ⋮\end{matrix} \\ 1\end{matrix} ) , ( \begin{matrix}− 1 \\ 0 \\ ⋮ \\ 0\end{matrix} ) , ( \begin{matrix}0 \\ − 1 \\ ⋮ \\ 0\end{matrix} ) , ⋯ , ( \begin{matrix}0 \\ 0 \\ ⋮ \\ − 1\end{matrix} ) \}$$

$$\text{?} \text{indicates text missing or illegible when filed}$$

The cubature point is then propagated through the state equation f as:

$${X}_{j , k \vert k − 1}^{⋆} = f ( {X}_{j , k − 1} )$$

Next, as shown in FIG. 6, a predicted error covariance is calculated, and a predicted state variable is calculated. After calculating the predicted state variable, the cubature point is recalculated. After recalculating the cubature point, a predicted measurement value is calculated, a measurement error covariance is calculated, and a measurement cross covariance is calculated, and then a Kalman gain is calculated. Also, after calculating the predicted state variable and the Kalman gain, an estimated state variable is calculated. Further, after calculating the predicted error covariance and the Kalman gain, an estimated error covariance is calculated. After calculating the estimated state variable and estimated error covariance, the value of k is incremented, the next cubature point is calculated, and the process is repeated until k is equal to N.

A Cholesky decomposition factor for the state equation and variance prediction is calculated as:

$${\overline{x}}_{k \vert k − 1} = {\sum }_{i = 1}^{m} {w}_{i} {X}_{i , k \vert k − 1}^{⋆}$$

$${P}_{k \vert k − 1} = \frac{1}{m} {\sum }_{i = 1}^{m} {{X}_{j , k \vert k − 1}^{⋆} ( {X}_{j , k \vert k − 1}^{⋆} )}^{T} - {\overline{x}}_{k \vert k − 1} {\overline{x}}_{k \vert k − 1}^{T} + Q$$

Cholesky decomposition is performed on the state prediction estimation variance P_{k|k-1}, obtaining:

$${P}_{k \vert k - 1} \qquad = {S}_{k \vert k − 1} {S}_{k \vert k − 1}^{T}$$

$${X}_{j , k \vert k + 1} \qquad = {\overline{S}}_{k \vert k + 1} {ξ}_{j} + {\overline{x}}_{k \vert k + 1}$$

A cubature point is propagated through the measurement equation h, and is recalculated as:

$$Z \text{?} = h ( {X}_{j , k \vert k - 1} )$$

$$\text{?} \text{indicates text missing or illegible when filed}$$

A measurement prediction, a Cholesky decomposition factor for a covariance, and the covariance are calculated as:

$${\overline{z}}_{k} = {\sum }_{i = 1}^{m} {w}_{i} {Z}_{i , k}$$

$$P \text{?} = \frac{1}{m} {\sum }_{i = 1}^{m} {Z}_{i , k} {Z}_{i , k}^{T} − {\overline{z}}_{k} {\overline{z}}_{k}^{T} + R$$

$$P \text{?} = \frac{1}{m} {\sum }_{j = 1}^{m} X \text{?} {Z}_{i , k}^{T} − {\overline{x}}_{k} {\overline{z}}_{k}^{T}$$

$$where$$

$$m = 2 n , {w}_{i} = \frac{1}{m} , i = 1 , 2 , … , m .$$

$$\text{?} \text{indicates text missing or illegible when filed}$$

4) The state is then updated.

A Kalman gain is calculated as:

$${W}_{k} = P \text{?} {( {P}_{z , k} )}^{- 1}$$

$$\text{?} \text{indicates text missing or illegible when filed}$$

A state variable is updated as:

$${\hat{x}}_{k} = {\overline{x}}_{k \vert k − 1} + {W}_{k} ( {z}_{k} − {\overline{z}}_{k} )$$

The error covariance is updated as:

$${P}_{k} = {P}_{k \vert k - 1} - {W}_{k} P \text{?} {W}_{k}^{T}$$

$$\text{?} \text{indicates text missing or illegible when filed}$$

The above implementation of the Kalman filtering is not limiting and is merely an illustration to facilitate understanding. In practice, the Kalman filtering may be implemented in another manner.

In summary, the device 200 according to the second embodiment includes the second filtering module 25 which is based on the Kalman filter model. The fourth state of charge is obtained through Kalman filtering and is determined as the state of charge of the battery estimated by the device 200. In this way, noise is further reduced, and accuracy and stability of estimation of the state of charge are improved.

### Third Embodiment

In the above description, some processes or methods are disclosed. Hereinafter, the methods/processes are described without repeating details described above. The methods/processes are not necessarily implemented or executed with the components as described above. For example, embodiments of a device for estimating a state of charge of a battery may be implemented partially or entirely using hardware and/or firmware, and the method for estimating a state of charge of a battery described below may be implemented entirely by a computer-executable program, although the method may be implemented by the hardware and/or firmware.

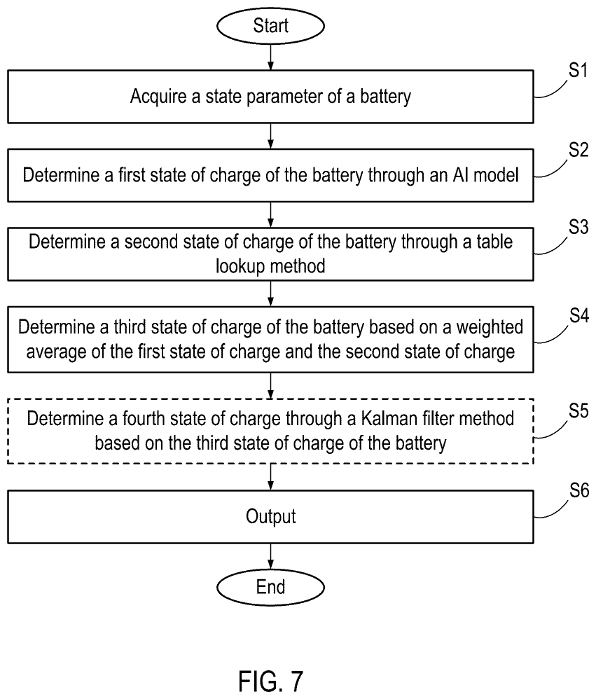

FIG. 7 illustrates a flowchart of a method for estimating a state of charge of a battery in an embodiment according to the invention.

In step S1, a state parameter of a battery is acquired.

In step S2, a first state of charge SOC_{AI} of the battery is calculated using a pre-trained AI model based on the acquired state parameter.

In step S3, a second state of charge of the battery is determined using a stored lookup table based on the acquired state parameter. The lookup table stores at least a portion of the state parameter and a state of charge of the battery in association with each other.

In step S4, a third state of charge SOC_{AI|lut} of the battery is determined by calculating a weighted average of the first state of charge SOC_{AI} and the second state of charge SOCₗᵤₜ based on weights of the first state of charge and the second state of charge.

As shown in FIG. 7, step S5 is optional (the dashed box indicates that the step is optional). Step S5 includes: obtaining a fourth state of charge SOC_{KF} through Kalman filtering based on the third state of charge SOC_{AI|lut} and the acquired state parameter, and determining the fourth state of charge SOC_{KF} as an estimated state of charge of the battery. Therefore, when step S5 is performed, the fourth state of charge SOC_{KF} is transmitted to step S6. When step S5 is not performed, the third state of charge SOC_{AI|lut} is transmitted to step S6.

In step S6, the received fourth state of charge SOC_{KF} (with execution of S5) or the received third state of charge SOC_{AI|lut} (without execution of S5) is determined as the estimated state of charge of the battery.

In embodiments, the state parameter in step S1 includes at least one of an open-circuit voltage, a terminal voltage, a current, and a temperature of the battery.

In an embodiment, the AI model in step S2 is further trained with the estimated state of charge of the battery and a corresponding state parameter to optimize a model parameter of the pre-trained AI model. The estimated state of charge outputted in S6 is transmitted to the AI model, and the AI model is trained with the estimated state of charge and a corresponding state parameter, until an output accuracy of the AI model reaches a predetermined threshold.

In an embodiment, the AI model in step S2 is a multi-layer neural network model including an input layer, at least two hidden layers, and an output layer. The input layer is for inputting the state parameter of the battery. Each hidden layer is provided with multiple neural network nodes, and each of the neural network nodes is assigned with an activation function. The output layer is for outputting the first state of charge calculated through the multi-layer neural network model.

In embodiments, the pre-stored lookup table in S3 includes one or both of an open-circuit voltage table and an RC table. The open-circuit voltage table stores a state of charge and an open-circuit voltage of the battery in association with each other. The RC table stores a state of charge and a terminal voltage, current, and temperature of the battery in association with each other.

In embodiments, in step S3, a lookup from the open-circuit voltage table is performed in a case where the battery is in an idle state, a constant-voltage charging state, or a low-current charging or discharging state, and a lookup from the RC table is performed in a case where the battery is in a state other than the idle state, the constant-voltage charging state, and the low-current charging or discharging state.

In embodiments, a lookup from the open-circuit voltage table in step S3 is performed through one-dimensional linear interpolation. In other embodiments, a lookup from the RC table in step S3 is performed through three-dimensional linear interpolation.

In embodiments, the weights in step S4 are determined based on at least the temperature and/or adjusted based on an actual estimation accuracy.

In embodiments, in step S4, one of the first state of charge and the second state of charge which has a higher accuracy than the other is assigned with a greater weight than the other.

In embodiments, in step S4, the weight of the first state of charge is greater than the weight of the second state of charge in a case where the temperature falls within a first temperature range; and the weight of the first state of charge is less than the weight of the second state of charge in a case where the temperature falls within a second temperature range that is higher than the first temperature range.

In embodiments, in S4, the weight of the first state of charge decreases as the temperature increases from the first temperature range to the second temperature range.

In embodiments, the weights in S4 are determined based on a range within which the temperature falls and a range within which the current falls, and a sum of the weight of the first state of charge and the weight of the second state of charge is equal to 1. If the current is beyond a current range stored in a lookup table, the weight of the first state of charge and the weight of the second state of charge are constants. If the current falls within the current range stored in the lookup table, the weight of the first state of charge is a first function of the temperature for the first temperature range, and the weight of the first state of charge is a second function of the temperature for the second temperature range.

In an embodiment, a demarcation point between the first temperature range and the second temperature range in step S4 is in a range from 15° C. to 20° C.

In an embodiment, the Kalman filter method in step S5 includes the following state equation and measurement equation.

The state equation is:

$$\{ \begin{matrix}{U}_{p , k} = ( 1 − \frac{Δ t}{τ} ) ⋆ {U}_{p , k − 1} + \frac{Δ t}{{C}_{p}} \cdot {I}_{k − 1} + {w}_{1} \\ S O {C}_{k} = S O {C}_{k − 1} + \frac{{I}_{k − 1} ⋆ Δ t}{{C}_{N}} + {w}_{2}\end{matrix}$$

The measurement equation is:

$$\{ \begin{matrix}{U}_{t , k} = {U}_{oc} − {U}_{p , k} − {R}_{0} ⋆ {I}_{k} + {v}_{1} \\ S O {C}_{k} = S O {C}_{AI \vert lut} + {v}_{2}\end{matrix}$$

In these equations, a polarization voltage Uₚ and a state of charge SOC are state variables, Δt represents a sampling time, C_{N} represents a rated battery capacity, R₀ represents a battery internal resistance, t represents a time constant, Cₚ represents a polarization capacitance, U_{oc} represents an open-circuit voltage, w₁ and w₂ represent system noises, and v₁ and v₂ represent measurement noises. Circuit model parameters R₀, τ, and Cₚ in the state equation may be estimated through a recursive least squares method. The example is provided merely to facilitate description and does not constitute a limitation on the Kalman filter method described in the present disclosure.

The method of FIG. 7 can be performed by the device 100 in the first embodiment and the device 200 in the second embodiment.

In summary, according to the method according in the embodiment of FIG. 7, the first state of charge of the battery is calculated using an AI model and the second state of charge of the battery is determined through a lookup table, and the final estimated state of charge of the battery is determined through filtering on the first state of charge and the second state of charge. In this way, noise is reduced, and accurate and stable estimation of the state of charge is achieved. In addition, the AI model may be further trained iteratively to update the AI model, so that noise is further reduced and the accuracy and stability of estimation of the state of charge is improved.

To facilitate understanding of the embodiments according to the present disclosure, examples of comparisons of estimated values of the state of charge obtained through different methods are described below.

Table 2 lists a comparison of errors of an estimated SOC output by a table lookup module and an estimated SOC output by an AI model according to embodiments of the present invention, relative to a real SOC (RSOC) in a case in which the same battery is discharged at different current points under a temperature of −10° C. In the first column, the Average SOCₗᵤₜ error indicates an error between the estimated SOC output by the table lookup module and the real RSOC of the battery, and the Average SOC_{AI} error indicates an error between the estimated SOC output by the AI module and the real RSOC of the battery. The Average SOCₗᵤₜ error and the Average SOC_{AI} error are in units of 10000; that is, two decimal places are retained for the SOC. The error ratio in the first column represents a ratio of an output of the AI model to an output of the table lookup model, that is,

$$\frac{SO {C}_{AI}}{SO {C}_{lut}} ⋆ 100 \% .$$

From table 2, at the temperature −10° C., an accuracy of SOCₗᵤₜ output by the table lookup module is significantly lower than an accuracy of SOC_{AI} output by the AI module at all the 6 current points. An average error of an output of the table lookup module is 1687.756 under a condition of discharging at a current of 2000 mA, and is 2209.971 under a condition of discharging at a current of 2500 mA, both of which do not satisfy an accuracy requirement for an SOC of a lithium battery. Therefore, at the temperature −10° C., the SOC_{AI} output by the AI module is more accurate and reliable. Therefore, for low-pass filtering by the first filtering module 14, the weight of the output of the AI module (weight in the equation) is set relatively higher.

TABLE 2
Comparison of SOC Errors at Different Current Points at −10° C.

| | 600 mA | 800 mA | 1200 mA | 1600 mA | 2000 mA | 2500 mA |
|---|---|---|---|---|---|---|
| Average | 856.655 | 660.416 | 1264.200 | 688.828 | 1687.756 | 2209.971 |
| SOCₗᵤₜ error | | | | | | |
| Average | 343.400 | 118.406 | 268.708 | 281.949 | 312.217 | 475.848 |
| SOC_{AI} error | | | | | | |
| Error ratio | 40.09% | 17.93% | 21.26% | 40.93% | 18.5% | 21.53% |

Table 3 lists a comparison of average errors of an estimated SOC output by a table lookup module and an estimated SOC output by an AI model according to the present invention, relative to a real RSOC in a case in which the same battery is discharged at different current points under different temperatures. The values are in units of 1000 that is, two decimal places are retained for an SOC. An error ratio indicates a ratio of an output of the AI model to an output of the table lookup model, that is,

$$\frac{SO {C}_{AI}}{SO {C}_{lut}} ⋆ 100 \% .$$

From table 3, at low temperatures −10° C., 0° C. and 15° C., an accuracy of SOCₗᵤₜ output by the table lookup module is lower than an accuracy of SOC_{AI} output by the AI module; and at normal and high temperatures 25° C., 40° C., and 45° C., an accuracy of SOCₗᵤₜ output by the table lookup module is higher than an accuracy of SOC_{AI} output by the AI module. In terms of the average errors, average errors of the AI model at the normal and high temperatures 25° C., 40° C. and 45° C. are 128.835, 108.020 and 178.058, respectively, all of which are less than the average errors at the low temperatures (−10° C. and 0° C.). Therefore, in the first filtering module 14, the weight of SOC_{AI} may be adjusted based on a temperature to ensure that the accuracy of estimation of state of charge at each temperature meets the requirement.

TABLE 3
Comparison of SOC Errors at Different Temperature Points

| | −10° C. | 0° C. | 15° C. | 25° C. | 40° C. | 45° C. |
|---|---|---|---|---|---|---|
| Average | 1032.630 | 947.535 | 143.460 | 66.572 | 37.827 | 39.617 |
| SOCₗᵤₜ error | | | | | | |
| Average | 277.607 | 285.448 | 132.118 | 128.835 | 108.020 | 178.058 |
| SOC_{AI} error | | | | | | |
| Error ratio | 26.88% | 30.13% | 92.09% | 193.53% | 285.56% | 449.45% |

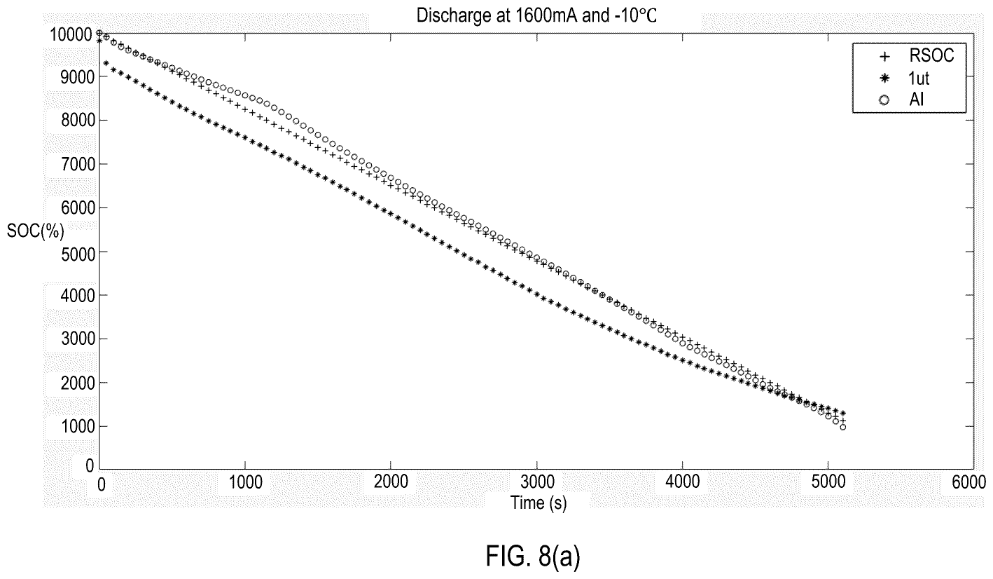

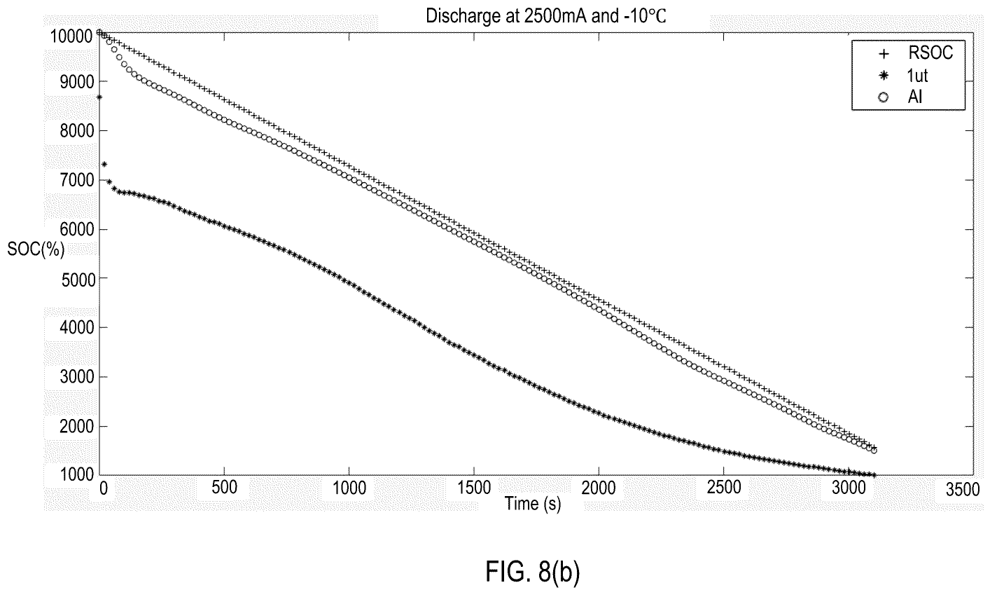

FIG. 8(a) shows a comparison of an estimated SOC output by the AI module (shown by a hollow circle symbol ∘ in the graph, indicating the first state of charge), an estimated SOC output by the table lookup module (shown by a star symbol * in the graph, indicating the second state of charge), and a real RSOC (shown by a cross symbol + in the graph) of the battery, under a condition of being discharged in a temperature of −10° C. and at a current point of 1600 mA.

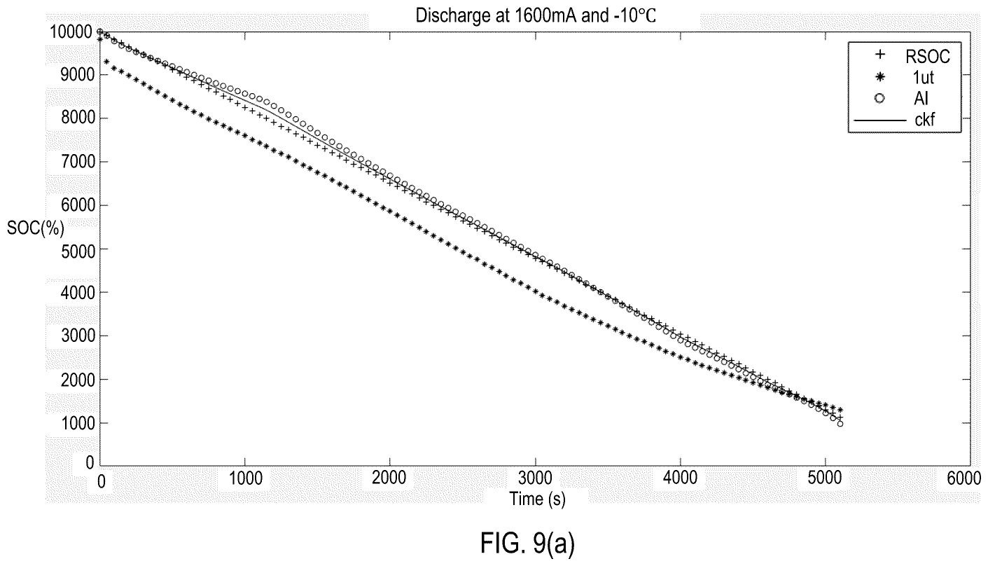

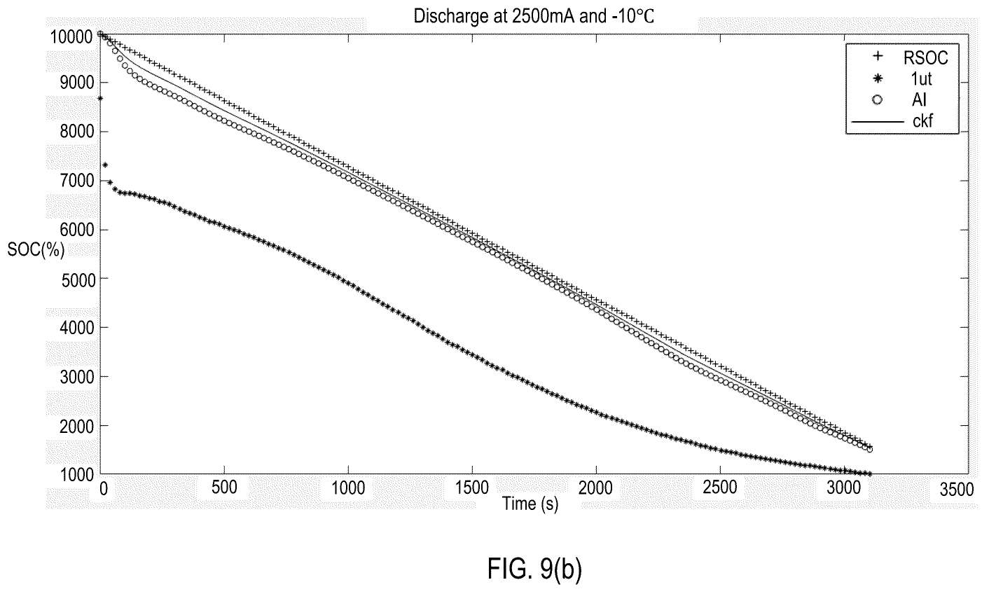

FIG. 8(b) shows a comparison of an estimated SOC output by the AI module (shown as a hollow circle symbol ∘ in the graph), an estimated SOC output by the table lookup module (shown as a star symbol * in the graph), and a real RSOC (shown as a cross symbol + in the graph) of the battery, under a condition of being discharged in a temperature of −10° C. and at a current point of 2500 mA. It can be seen that in a low-temperature environment, the accuracy of SOC_{AI} output by the AI module is higher than the accuracy of SOCₗᵤₜ output by the table lookup module. Therefore, by way of example and not limitation, the weight of SOC_{AI} is set to 0.98, for example, for a filtering module to reduce an accuracy error caused by the table lookup module. FIG. 9(a) and FIG. 9(b) show the estimated SOC output by the device 200 as described in the second embodiment (in which low-pass filtering and Kalman filtering are performed based on the weight), providing a comparison with the results shown in FIG. 8(a) and FIG. 8(b).

FIG. 9(a) shows a comparison of an estimated SOC output by the second filtering module (shown by a thin solid line in the graph, indicating the fourth state of charge) as in the second embodiment, an estimated SOC from the AI module (shown by a hollow circle symbol ∘ in the graph, indicating the first state of charge), an estimated SOC from the table lookup module (shown by a star symbol * in the graph, indicating the second state of charge), and a real RSOC (shown by a cross symbol + in the graph) of the battery, under a condition of being discharged in a temperature of −10° C. and at a current point of 1600 mA.

FIG. 9(b) shows a comparison of an estimated SOC output by the second filtering module (shown by a thin solid line in the graph), an estimated SOC from the AI module (shown by a hollow circle symbol ∘ in the graph), an estimated SOC from the table lookup module (shown by a star symbol * in the graph), and a real RSOC (shown by a cross symbol + in the graph) of the battery, under a condition of being discharged in a temperature of −10° C. and at a current point of 2500 mA.

It can be seen from FIG. 9(a) and FIG. 9(b) that an average error and a maximum error of the estimated SOC output by the second filter module relative to the real RSOC of the battery are the minimum. Therefore, the method combining the AI model and the lookup table for SOC estimation has high accuracy and wide application scope.

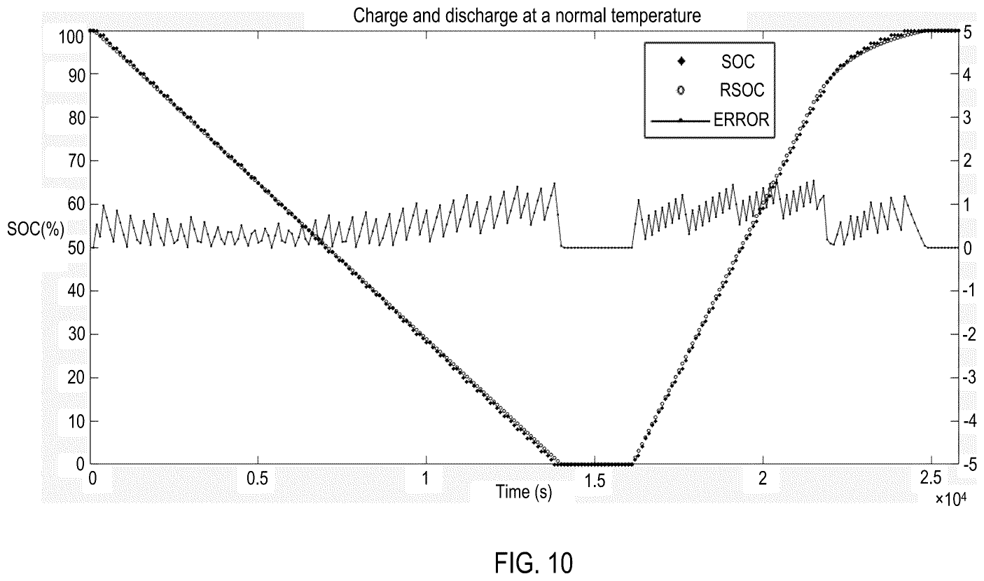

FIG. 10 shows a comparison of an estimated SOC and a real RSOC of a battery in a single charging and discharging process at 25° C. In FIG. 10, the solid rhombus symbol represents the estimated SOC, and the hollow circle symbol represents the real RSOC of the battery, both of which correspond to the left vertical axis coordinates. The dotted solid line represents an error (corresponding to the right vertical axis coordinates). It can be seen from FIG. 10 that in a complete charging and discharging process of a lithium battery, a maximum error and an average error of the estimated SOC relative to the real RSOC of the battery are 1.7679 and 0.5372, respectively, indicating that the estimation accuracy for a state of charge of the battery is significantly improved in practice.

The basic principle of the present disclosure has been described above in conjunction with specific embodiments. However, for those skilled in the art, all or any of the steps or components of the method and apparatus according to the disclosure can be implemented in a form of hardware, firmware, software or a combination thereof in any computing device (including a processor, a storage medium and the like) or a network of computing devices. Such implementation can be realized by those skilled in the art after reading the description of the present disclosure, by utilizing general knowledge in circuitry design or general programming skills.

Moreover, a program product in which machine-readable instruction codes are stored is further provided according to the present disclosure. The instruction codes, when read and executed by the machine, perform the aforementioned methods according to the embodiments of the present disclosure.

Accordingly, a storage medium for carrying the program product storing the machine-readable instruction codes is further provided according to the present disclosure. The storage medium includes, but is not limited to, a floppy disk, an optical disk, a magneto-optical disk, a storage card, a memory stick and the like.

In a case of implementing the present disclosure by software or firmware, a program constituting the software is installed from a storage medium or a network to a computer with a dedicated hardware structure. The computer, when installed with various programs, can execute various functions and the like.

In the apparatus, method and system according to the present disclosure, the components or steps may be decomposed and/or recombined. Such decomposition and/or recombination should be considered equivalents of the present disclosure. Furthermore, the above series of processing steps may naturally be performed temporally in the sequence as described above but are not limited thereto. Some steps may be performed in parallel with or independently from each other.

The terms “include”, “comprise” or any variants thereof are intended to be non-exclusive. Therefore, a process, method, article or apparatus including a series of elements includes not only the elements but also other elements that are not enumerated, or further includes the elements inherent to the process, method, article or apparatus. Unless expressively limited otherwise, the element defined by the statement “including a . . . ” does not exclude existence of other same elements in the process, method, article or apparatus.

Although the embodiments of the present disclosure have been described above in detail in connection with the drawings, the embodiments described above are merely illustrative rather than limitative of the present disclosure. Those skilled in the art may make various modifications and variations to the above embodiments without departing from the spirit and scope of the present disclosure. Therefore, the scope of the present disclosure is defined merely by the appended claims and their equivalents.

What is claimed is:

1. A device operable for determining a state of charge of a battery, comprising:
an acquisition circuit configured to acquire state parameters of the battery; and
a processing circuit, coupled to the acquisition circuit, and configured to:
calculate a first state of charge of the battery using a pre-trained artificial intelligence (AI) model based on the state parameters acquired by the acquisition circuit;
determine a second state of charge of the battery using a stored lookup table and the state parameters acquired by the acquisition circuit, wherein the lookup table stores states of charge as a function of at least a portion of the state parameters, and
determine a third state of charge of the battery by calculating a weighted average of the first state of charge of the battery and the second state of charge of the battery.

2. The device according to claim 1, wherein the processing circuit is further configured to:
determine a fourth state of charge based on Kalman filtering of the state parameters acquired by the acquisition circuit and the third state of charge.

3. The device according to claim 1, wherein the processing circuit is further configured to:
further train the pre-trained AI model using the third state of charge of the battery and the state parameters corresponding to the third state of charge.

4. The device according to claim 1, wherein the stored lookup table comprises one or more of an open-circuit voltage table and a resistor-capacitor (RC) table, and wherein:
the open-circuit voltage table stores state of charge values indexed by of the battery open-circuit voltage values; and
the RC table stores state of charge values indexed by terminal voltage, current, and temperature values.

5. The device according to claim 4, wherein the processing circuit is configured to:
perform a table lookup with the open-circuit voltage table if the battery is in an idle state, a constant-voltage charging state or a low-current charging or discharging state; and otherwise perform a table lookup with the RC table.

6. The device according to claim 4, wherein the processing circuit is configured to:
perform a table lookup with the open-circuit voltage table through a one-dimensional linear interpolation method; and
perform a table lookup with the RC table through a three-dimensional linear interpolation method.

7. The device according to claim 1, wherein the state parameters comprise at least one of an open-circuit voltage of the battery, a terminal voltage of the battery, a current of the battery, and a temperature of the battery.

8. The device according to claim 7, wherein weights for calculating the weighted average are determined based on the temperature and are optionally adjusted based on an accuracy of the first state of charge and an accuracy of the second state of charge.

9. The device according to claim 8, wherein the weights are also determined based on which one of the first state of charge of the battery and the second state of charge of the battery has a higher accuracy relative to the other one, and wherein the one with the higher accuracy is assigned with greater weight than the other one.

10. The device according to claim 8, wherein:
a weight of the first state of charge of the battery is greater than a weight of the second state of charge of the battery if the temperature is within a first temperature range; and
a weight of the first state of charge of the battery is smaller than a weight of the second state of charge of the battery if the temperature is within a second temperature range that is higher than the first temperature range.

11. The device according to claim 10, wherein:
the weights are also determined based on an interval within which the temperature falls and a range within which the current falls, and a sum of a weight of the first state of charge of the battery and a weight of the second state of charge of the battery is equal to 1;
if the current is outside a range of current stored in the lookup table, then the weight of the first state of charge of the battery and the weight of the second state of charge of the battery are both constants; and
if the current is within the range of current stored in the lookup table, then the weight of the first state of charge of the battery is a first function of the temperature for the first temperature range, and the weight of the first state of charge of the battery is a second function of the temperature for the second temperature range.

12. The device according to claim 11, wherein a demarcation point between the first temperature range and the second temperature range is within an interval from 15 degrees Celsius to 20 degrees Celsius.

13. The device according to claim 1, wherein:
the AI model is a multi-layer neural network model comprising an input layer, at least two hidden layers, and an output layer;
the input layer is for inputting the state parameters of the battery;
each of the hidden layers comprises a plurality of neural network nodes, and each of the neural network nodes is assigned an activation function; and
the output layer is for outputting the first state of charge of the battery determined by the multi-layer neural network model.

14. A method for determining a state of charge of a battery, the method comprising:
accessing state parameters of the battery;
calculating a first state of charge of the battery using a pre-trained artificial intelligence (AI) model based on the state parameters;
determining a second state of charge of the battery using a stored lookup table and the state parameters, wherein the lookup table stores states of charge as a function of at least a portion of the state parameters, and
determining a third state of charge of the battery by calculating a weighted average of the first state of charge of the battery and the second state of charge of the battery.

15. The method according to claim 14, further comprising:
determining a fourth state of charge based on Kalman filtering of the third state of charge and the state parameters.

16. The method according to claim 14, further comprising:
further training the pre-trained AI model based on the third state of charge of the battery and the state parameters corresponding to the third state of charge.

17. The method according to claim 14, wherein the stored lookup table comprises one or more of an open-circuit voltage table and an RC table, and wherein:
the open-circuit voltage table stores state of charge values indexed by of the battery open-circuit voltage values; and
the RC table stores state of charge values indexed by terminal voltage, current, and temperature values.

18. A computer program product comprising computer-executable instructions that, when executed by a processor, cause the processor to perform the method according to claim 14.
